(19) United States
(12) Patent Application Publication
(10) Pub. No.: US 2009/0174036 A1
(43) Pub. Date: Jul. 9, 2009

(54) PLASMA CURING OF PATTERNING MATERIALS FOR AGGRESSIVELY SCALED FEATURES

(75) Inventors: Nicholas C. Fuller, North Hills, NY (US); Michael A. Guillorn, Yorktown Heights, NY (US); Hirohisa Kawasaki, Yorktown Heights, NY (US); Atsushi Yagishita, Somers, NY (US)

Correspondence Address: SCULLY, SCOTT, MURPHY & PRESSER, P.C., 400 GARDEN CITY PLAZA, SUITE 300, GARDEN CITY, NY, 11530, US

(73) Assignees: INTERNATIONAL BUSINESS MACHINES CORPORATION, Armonk, NY (US); TOSHIBA AMERICA ELECTRONIC COMPONENTS, INC., Irvine, CA (US)

(21) Appl. No.: 11/969,525

(22) Filed: Jan. 4, 2008

(51) Int. Cl. H01L 29/30; G03F 7/26

(52) U.S. Cl. 257/618; 430/313; 257/E29.106

(57) ABSTRACT

A methodology is disclosed that enables the fabrication of semiconductor devices (i.e., STI structures, gates, and interconnects) with significantly reduced line edge roughness (LER) and line width roughness (LEW) post lithography patterning. The inventive methodology entails the use of an inert species containing plasma tuned to enhanced its' vacuum ultra violet (VUV) emissions post lithography and/or post one of the etch processes of a given feature (on an identical etch platform) to entice increased crosslinking of one or more patterning materials, thus enabling increased etch resistance and reduced LER and LEW post etching processing.

### FIELD OF THE INVENTION

The present invention generally relates to semiconductor integrated circuits (ICs), and more particularly to semiconductor devices and/or interconnect structures in which a method is employed for reducing post lithographic patterning line edge roughness (LER) and line width roughness (LWR) for device and interconnect features for 45 nm and beyond technologies. The inventive method achieves increased device and interconnect structural uniformity and enables high speed devices and ring oscillators.

### BACKGROUND OF THE INVENTION

Generally, semiconductor devices include a plurality of circuits which form an integrated circuit (IC) including chips, thin film packages and printed circuit boards. Integrated circuits can be useful for computers and electronic equipment and can contain millions of transistors and other circuit elements that are fabricated on a semiconductor substrate, particularly, a single silicon crystal substrate.

For planar or three-dimensional (FinFET, TriGate, and etc.) complementary metal oxide semiconductor (CMOS) devices, e.g., p-type field effect transistor (pFET) and n-type field effect transistor (nFETs) gates made of polysilicon (polySi) and/or a high k dielectric and metal materials; and interconnect structures made of Cu and a low k dielectric, to be functional a minimal line edge roughness (LER) and a minimal line width roughness (LWR) is required to enable faster devices and ring oscillators.

For current 65 nm CMOS devices, polySi gates of 100 nm thickness and a 40 nm critical dimension (CD) and a first metal line level pitch of approximately 200 nm (note: 100 nm equals a line and a space) are employed. For future technologies where continued device shrinking will be required for achieving higher performance devices and high speed ring oscillators, it is essential that processing methodologies are developed to facilitate minimal LER and LWR of all these key features as well as other features.

Post patterning measurements of gates, shallow trench isolation (STI) and line features for 45 nm and beyond technologies employing immersion lithography reveal LER values of greater than, or equal to, 2.5 nm, and LWR values of greater than, or equal to, 5.0 nm. While such LER and LWR values maybe acceptable for minimum feature sizes of about 100 nm, they are not acceptable for feature sizes that are less than 40 nm because such LER/LWR values partially impede the ability to achieve higher speed ring oscillators to meet the technology requirements.

Thus, it is clear that improved lithography and/or some other means of reducing LER/LWR for all these critical features is needed to truly enable 45 nm and beyond CMOS technologies.

U.S. Pat. No. 7,160,671 to Ko et al. relates to a lithographic method that can be used in reducing the minimum feature sizes of semiconductor devices. More particularly, the '671 patent provides a method for increasing the etch selectivity of a developed silicon-containing photoresist layer on a substrate. In accordance with the teaching of the '671 patent, the selectivity of an etch process to a silicon-containing photoresist layer can be increased by exposing a developed silicon-containing photoresist layer to ultra-violet (UV) light that emanates from a UV generating agent. The UV exposed portion of the developed silicon-containing photoresist layer is hardened by crosslinking the polymer chains containing silicon.

The '671 patent is based on the finding that silicon-containing photoresists are sensitive to a wavelength of light that is in the UV range (approximately 200 to 350 nm). As such, the process disclosed in the '671 patent is limited to silicon-containing photoresists.

In view of the above, there is a continued need for developing a method that has universal applications and can effectively reduce post patterning LER and LWR for various semiconductor structures, including CMOS, shallow trench isolation, metal contacts, metal lines and interconnect features.

### SUMMARY OF THE INVENTION

The present invention provides a methodology that enables the fabrication of semiconductor devices (such as, for example, STI structures, gates, and interconnects) with significantly reduced line edge roughness (LER) and line width roughness (LWR) post lithographic patterning. The inventive methodology entails the use of an inert species containing plasma ‘tuned’ to enhance its' vacuum ultra violet (VUV) emissions post lithography and/or post one of the etch processes of a given feature (on an identical etch platform) to entice increased crosslinking of one or more patterning materials, thus enabling increased etch resistance and reduced LER and LWR post etch processing.

In one embodiment, and by way of an example, 20 nm gate structures on an 80 nm pitch fabricated utilizing the inventive methodology were able to achieve a reduction in post lithographic LER and LWR from 2.6 nm LER and 4.9 nm LWR to 1.4 nm LER and 2.3 nm LWR. Thus, the methodology of the present invention provided, in this example, a 50% reduction on LER and LWR.

More specifically, the methodology of the present invention employs an inert species containing plasma as a VUV source to improve the robustness of one or more utilized patterning materials in single or multiple steps post lithography and/or post etching to improve selectivity and, more importantly, reduce LER/LWR enabling faster speed circuits and ring oscillators. It is emphasized that the VUV emissions provided in the present invention are within a wavelength range from about 10 nm to about 100 nm.

Unlike the prior art method disclosed in the '671 patent mentioned above, the inventive methodology is not limited to applications that employ silicon-containing materials. Instead, the inventive methodology can be used for applications including a wide variety of photoresists and/or patterning materials.

In addition to the above, the inventive method is applicable for forming improved, in turns of a reduced LER/LWR, gate structures, shallow trench isolation (STI) structures or interconnect structures.

In general terms the present invention provides a method of fabricating a semiconductor structure having reduced LER/LWR values, comprising:

exposing at least one preprocessed patterning material located on a substrate to vacuum ultra violet (VUV) emissions to induce crosslinking of said at least one preprocessed patterning material, said VUV emissions are generated by an inert species containing plasma.

The substrate employed in the present invention typically includes at least one material layer to be subsequently patterned by a patterning transfer etching process which occurs after performing the above exposing step.

The term “preprocessed patterning material” is used throughout this application to denote any material including, for example, a photoresist, a patternable low k dielectric, an organic planarizing material and/or an antireflective coating (ARC), that can be used for providing a pattern into a material layer located within or on a substrate, and that has been previously subjected to photolithography, etching or a combination of photolithography and etching, i.e., any patterning material post lithography and/or post etching.

In one embodiment, the preprocessed patterning material has been subjected to lithography (i.e., exposure to a pattern of radiation and developed) prior to exposing the same to VUV emissions.

In another embodiment of the present invention, the preprocessed patterning material has been subjected to at least one etching step prior to exposing the same to VUV emissions.

In yet another embodiment of the present invention, the preprocessed patterning material has been subjected to lithography (i.e., exposure to a pattern of radiation and developed) and at least one etching step prior to exposing the same to VUV emissions.

In a further embodiment of the present invention, the at least one material layer to be patterned includes a semiconductor material, a dielectric material, a conductive material, or any combination thereof such as a dielectric material and a conductive material.

In one example, and in the case of a CMOS structure, the at least one material layer to be patterned is a gate conductor. In another example, and in the case of a CMOS structure, the least one material layer to be patterned is a gate stack comprising a gate conductor and a gate dielectric. In yet another example, and in the case of a shallow trench isolation structure, the at least one material layer to be patterned is a semiconductor material. In a further example, and in the case of interconnect structure, the at least one material to be patterned is a dielectric material.

In one embodiment of the present invention, the inert species containing plasma includes He, Kr, Ar, Xe, Ne or combinations thereof. In a preferred embodiment, the inert species containing plasma comprises He.

In an embodiment of the invention, VUV emissions are generated utilizing an inert species containing plasma that has been subjected to a pressure of less than about 100 mT, a high source power of greater than about 500 W, a bias power of less than about 50 W, and a substrate temperature of less than, or equal to, about 60° C. In a preferred embodiment of the present invention, the pressure used in generating the VUV emissions is less than about 50 mT and the bias power is 0 W.

In addition to the above, the present invention also provides a semiconductor structure (i.e., CMOS structure, STI structure, and/or interconnect structure) having at least one feature defined by a patterned material layer, wherein said at least one feature has a line edge roughness (LER) of 1.4 nm or less and a line width roughness (LWR) of 2.3 nm or less.

### BRIEF DESCRIPTION OF THE DRAWINGS

FIGS. 1A-1B are pictorial representations (through cross sectional views) illustrating some basic patterning schemes including at least one preprocessing patterning material located atop a substrate including a semiconductor substrate and a material stack comprising a dielectric material and a conductive material located on a surface of the semiconductor substrate, post lithography, but prior to VUV exposure.

FIGS. 2A-2B are pictorial representations (through cross sectional views) illustrating the structures of FIGS. 1A and 1B, respectively, after VUV exposure.

FIGS. 3A-3B are pictorial representations (through cross sectional views) illustrating some basic patterning schemes including at least one preprocessing patterning material located atop a substrate including a semiconductor substrate and a material stack comprising a dielectric material and a conductive material located on a surface of the semiconductor substrate, post lithography and etching, but prior to VUV exposure.

FIGS. 4A-4B are pictorial representations (through cross sectional views) illustrating the structures of FIGS. 3A and 3B, respectively, after VUV exposure.

FIGS. 5A-5C are SEMS of 20 nm gate structures which were patterned utilizing the inventive method of the present application, FIG. 5A represents post litho exposure, FIG. 5B represents a post gate etch in which a bottom most preprocessing patterning material has been processed through VUV exposure after one stage of the etch process, and FIG. 5C represents a post gate etch in which two preprocessing patterning materials have been processed through VUV exposure, the topmost material after litho and the bottom most after one stage of the etch process.

### DETAILED DESCRIPTION OF THE INVENTION

The present invention, which provides a method for reducing post lithography patterning line edge roughness (LER) and line width roughness (LWR) and a structure formed by the inventive method, will now be described in greater detail by referring to the following discussion and drawings that accompany the present application. It is noted that the drawings of the present application are provided for illustrative purposes only and, as such, the drawings are not drawn to scale.

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As stated above, the present invention provides a method that enables the fabrication of semiconductor devices (such as, for example, STI structures, gates, and interconnects) with significantly reduced LER and LWR post lithographic patterning. Typically, a reduction of about 50% or less in both LER and LWR can be obtained by utilizing the method of the present invention for a given structure (STI structure, CMOS device, or interconnect structure). The inventive method employs an inert species containing plasma ‘tuned ‘to enhance its’ vacuum ultra violet (VUV) emissions post lithography and/or post one of the etch processes of a given feature (on an identical etch platform) to entice increased crosslinking of one or more patterning materials, thus enabling increased etch resistance and reduced LER and LEW post etching processing.

The post etching processing includes any high density (inductively coupled plasma (ICP), electron cyclotron resonance (ECR), microwave, helicon, etc.) or medium density (dual or triple frequency capacitively coupled) source. In both instances, however, the powered source electrode should be located at the top of the reactor etching chamber, and not the substrate so as to maintain a negligible ion current (plasma potential apart) to the substrate surface. The frequencies of the powered source electrode should be greater than, or equal to, 2 MHz with a value of greater than, or equal to, 60 MHz being preferred.

More specifically, the method of the present invention employs an inert species containing plasma as a VUV source to improve the robustness of one or more utilized patterning materials in single or multiple steps post lithography and/or post etching to improve selectivity and, more importantly, reduce LER/LWR enabling faster speed circuits and ring oscillators. It is emphasized that the VUV emissions provided in the present invention are within a wavelength range from about 10 nm to about 100 nm. In one embodiment of the present invention, the inert species containing plasma includes He, Kr, Ar, Xe, Ne or combinations thereof. In a preferred embodiment, the inert species containing plasma comprises He.

In an embodiment of the invention, VUV emissions are generated utilizing an inert containing plasma that has been subjected to a pressure of less than about 100 mT, a high source power of greater than about 500 W, a bias power of less than about 50 W, and a substrate temperature of less than, or equal to, about 60° C. In a preferred embodiment of the present invention, the pressure used in generating the VUV emissions is less than about 50 mT and the bias power is 0 W.

The inert species containing plasma and the subsequent VUV emissions can be generated in any apparatus that is capable of generating a plasma from an inert gas source. The VUV emissions are obtained using the conditions described above. Tuning the emission to a desired wavelength within the VUV range can be achieved by adjusting at least one of the parameters mentioned above.

In addition to the above, the inventive method is applicable for forming improved, in turns of a reduced LER/LWR, gate structures, shallow trench isolation (STI) structures or interconnect structures.

In general terms, the present invention provides a method of fabricating a semiconductor structure having reduced LER/LWR values which includes exposing at least one preprocessed patterning material located on a substrate to vacuum ultra violet (VUV) emissions to induce crosslinking of said at least one preprocessed patterning material, said VUV emissions are generated by an inert species containing plasma.

The substrate employed in the present invention typically includes at least one material layer to be subsequently patterned by a pattern transfer etching process which occurs after performing the above exposing step.

As stated above, the term “preprocessed patterning material” denotes any material including, for example, a photoresist, a patternable low k dielectric, an organic planarizing material and/or an antireflective coating (ARC), that can be used for providing a pattern into a material layer located within or upon a substrate, and that has been previously subjected to photolithography, etching or a combination of photolithography and etching, i.e., any patterning material post lithography and/or post etching.

When a photoresist is employed as the preprocessed patterning material, the photoresist may include any conventional photoresist (organic, inorganic or hybrid) that is well known to those skilled in the art. The photoresist may be Si-containing or non-silicon-containing. Examples of suitable photoresists that can be used in the present invention include, but are not limited to optical resist layers that are sensitive to at least to one of broadband ultraviolet radiation, 436 nm wavelength g-line ultraviolet radiation, 365 nm wavelength i-line ultraviolet radiation, 248 nm wavelength KrF excimer ultraviolet radiation, 193 nm wavelength ArF excimer ultraviolet radiation, 157 nm wavelength F₂ laser, and extreme ultraviolet radiation; electron beam sensitive resist materials including hydrogen sesquioxane (HSQ), aluminum fluoride (AlF), zinc oxide (ZrO), and titanium oxide (TiO₂). HSQ can also be used for printing patterns using 157 nm deep ultraviolet (DUV), extreme ultraviolet (EUV) and X-ray lithography.

When a patternable low k dielectric is used, any material disclosed within co-assigned U.S. Pat. No. 7,041,748 to Lin et al., the entire contents of which are incorporated herein by reference, may be employed. That is, a functionalized polymer having one or more acid-sensitive imageable groups can be used in the present application. The functional polymers are low k polymers or polymers that can be converted into low k polymers after subsequent processing, either by heat or light. More specifically, the polymers employed in the present invention include, but are not limited to hydrocarbons, fluorinated hydrocarbons, organosilicates, silsesquioxanes and the like. Of these polymers, silsesquioxane-type polymers including caged, linear, branched or combinations thereof, are preferred, with caged silsesquioxane polymers being more highly preferred.

The one or more acid-sensitive imageable groups include, for example, acid-sensitive positive-tone functional groups or acid-sensitive negative-tone functional groups. The negative-tone functional groups are functional groups for causing a crosslinking reaction (crosslinking can be effected by the functional group itself or by a crosslinking agent), while the positive-tone functional groups are acid-sensitive protecting groups. When negative-tone functional groups are employed, a photo-chemically generated acid catalyzes the crosslinking of the functonal groups, either with or without an additional agent, to render the exposed area insoluble in a developer. Subsequently development with a proper developer generates negative-tone relief images. When positive-tone functional groups are employed, a photo-chemically generated acid catalyzes the deprotection of the acid sensitive protecting functional groups to render the exposed area soluble in a developer. Subsequently development with a proper developer generates positive-tone relief images.

When an ARC is used as the patterning material, any material that has an antireflective surface can be used including but not limited to siloxane polymers, hydrogensiloxane polymers, and hydrogensilsesquioxane polymers.

When an organic planarizing material is employed as the patterning material, any organic containing material that can provide a planar surface can be used including, for example, non-frictionless carbon (NFC), diamond like carbon (DLC), thermosetting polyarylene ethers, amorphous carbon materials, poly(stryenes), poly(esters), poly(methacrylates), poly(acrylates), poly(glycols), poly(amides), poly(norbornenes), or combinations thereof.

In one embodiment, the preprocessed patterning material has been subjected to lithography (i.e., exposure to a pattern of radiation and developed) prior to exposing the same to VUV emissions. In another embodiment of the present invention, the preprocessed patterning material has been subjected to at least one etching step prior to exposing the same to VUV emissions. In yet another embodiment of the present invention, the preprocessed patterning material has been subjected to lithography (i.e., exposure to a pattern of radiation and developed) and at least one etching step prior to exposing the same to VUV emissions.

In a further embodiment of the present invention, the at least one material layer to be patterned includes a semiconductor material, a dielectric material, a conductive material, or any combination thereof such as a dielectric material and a conductive material.

The term “semiconductor material” denotes any material that has semiconducting properties. Illustrative examples of such semiconductor materials having semiconducting properties include, but are not limited to Si, SiGe, Ge, Ge alloys, GaAs, InAs, InP and all other III/V semiconducting compounds. Layered semiconductor materials such as, for example, Si/SiGe, silicon-on-insulators (SOI) and SiGe-on-insulators (SGOI) are also contemplated herein. The semiconductor material may be undoped, doped or contain doped regions and undoped regions. The doped regions typically include atoms of Group IIIA or VA of the Periodic Table of Elements; the nomenclature IIIA and VA is in accordance with a CAS version of the Periodic Table.

In some embodiments of the present invention, the semiconductor material can be strained, unstrained or it may contain regions of strain and unstrain therein. The semiconductor material may have a single crystal orientation, or it may have surface regions that have a different crystallographic orientation.

The term “dielectric material” as used in the present application includes any material that has insulating properties. Illustrative examples of dielectric materials having insulating properties include, but are not limited to oxides, nitrides, oxynitrides, organic polymers, interconnect dielectrics and any combination thereof. In one embodiment, the dielectric material may have a dielectric constant that is equal to, or greater than, the dielectric constant of silicon dioxide. Illustrative examples, of such dielectrics include, but are not limited to silicon dioxide, silicon nitride, silicon oxynitride, Al₂O₃, and/or HfO₂. In such an embodiment, the dielectric material can be used as a gate dielectric or an insulating material of an isolation structure.

In yet another embodiment, the dielectric material is an insulator having a dielectric constant that is less than that of silicon dioxide. In this embodiment, porous, nonporous or a combination of porous and non-porous dielectrics are contemplated. Illustrative examples of such ‘low k’ dielectric materials include, but are not limited to silsesquioxanes, C doped oxides (i.e., organosilicates) that includes atoms of at least Si, C, O and H, thermosetting polyarylene ethers or multilayers thereof. The term “polarylene” is used herein to denote aryl moieties or inertly substituted aryl moieties that are crosslinked together by bonds, fused rings, or inert linking groups such as, for example, oxygen, sulfur, sulfone, sulfoxide, carbonyl and the like. In this embodiment, the dielectric material can be used as a gate dielectric or an interconnect dielectric.

The term “conductive material” is used in the present application denote any material that has conductive properties. Illustrative conductive materials include, but are not limited to doped polysilicon, doped polySiGe, a conductive metal, an alloy comprising at least one conductive metal, a conductive metal silicide and combinations and multilayered stacks thereof. In some embodiments, the conductive metal is a gate conductor located atop a dielectric material. In another embodiment, the conductive material is a metal line, a contact, or a component of an interconnect structure. An interconnect structure includes an interconnect dielectric which typically includes a conductive material (typically Cu, Al or alloys of Cu—Al) embedded with the interconnect dielectric.

The following description illustrates an embodiment of the present application in which the inventive method is employed in reducing the LER and the LWR roughness of a gate stack of a CMOS structure. Although this particularly illustration is provided, the present invention is not limited in applications directed to forming CMOS structures. Instead, the inventive method described herein can be used in reducing the LER and the LWR of other types of semiconductor structures including, for example, interconnect structures and trench isolation structures.

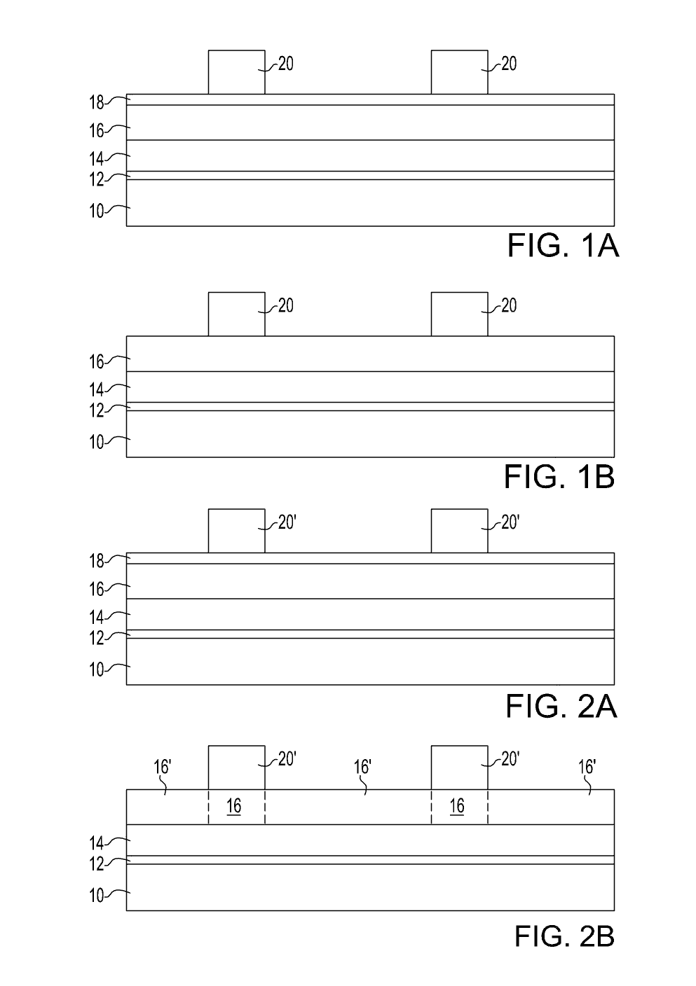

Reference is first made to FIGS. 1A-1B which are pictorial representations (through cross sectional views) illustrating some basic patterning schemes in which the inventive method can be used. Each of the patterning schemes illustrated are post lithography, but prior to VUV exposure. FIG. 1A illustrates a first patterning scheme that includes a semiconductor substrate 10, a gate dielectric 12 located on the surface of the semiconductor substrate 10, a gate conductor 14 located on the surface of the gate dielectric 12, an organic planarizing material 16 located on the surface of a gate conductor 14, an oxide hard mask 18 located on the surface of the organic planarizing material 16 and a patterned photoresist 20 located on the surface of the oxide hard mask 18. The patterned photoresist 20 has been subject to lithography (i.e., exposure to a pattern of radiation and development).

FIG. 1B illustrates a second patterning scheme that includes a semiconductor substrate 10, a gate dielectric 12 located on the surface of the semiconductor substrate 10, a gate conductor 14 located on the surface of the gate dielectric 12, an organic planarizing material 16 located on the surface of a gate conductor 14 and a patterned photoresist 20 located on the surface of the organic planarizing material 16. The patterned photoresist 20 has been subject to lithography (i.e., exposure to a pattern of radiation and development).

It is noted that the semiconductor substrate 10, the gate dielectric 12, the gate conductor 14, the organic planarizing material 16 and the patterned photoresist 20 include one of the materials described above. Each of the components in the patterning schemes illustrated in FIGS. 1A-1B are formed utilizing conventional processes that are well known to those skilled in the art. So as not to obscure the inventive method, the details regarding formation of each of the components within FIGS. 1A-1B are not provided herein.

FIGS. 2A-2B are pictorial representations (through cross sectional views) illustrating the structures of FIGS. 1A and 1B, respectively, after VUV exposure utilizing conditions mentioned herein above. In FIGS. 2A-2B, like reference numerals are used for describing like components that are not effected by VUV exposure. Reference numerals including a prime designation, i.e., patterned photoresist 20′ and organic planarizing material 16′ represent components within the patterning schemes that are affected by the VUV exposure.

The VUV exposure serves to increase crosslinking of the VUV exposed patterning materials (i.e., patterned photoresist 20 and organic planarizing material 16). Note that in the first patterning scheme in FIG. 1A-2A, the organic planarizing material 16 is not subjected to VUV exposure since an oxide hard mask 18 is located on the surface thereof during the VUV exposure. The increased crosslinking within the VUV exposed patterning materials increases the robustness of the patterning materials, i.e., patterned photoresist 20 and organic planarizing material 16. It is noted that the depth of penetration of the VUV radiation into the exposed organic planarizing material 16 of the second scheme illustrated in FIGS. 2A-2B is dependent on the absorption depth of the specific material at wavelengths less than 100 nm.

Subsequent to the application of the inventive method, one of the etching processes mentioned above is performed to transfer the pattern into at least the underlying gate conductor 14. In some embodiments, and after a first pattern transfer step, a second exposure with VUV radiation may be performed. Such an embodiment may be performed when the pattern within FIG. 2A is transferred into the oxide hard mask by etching and then into the organic planarizing material.

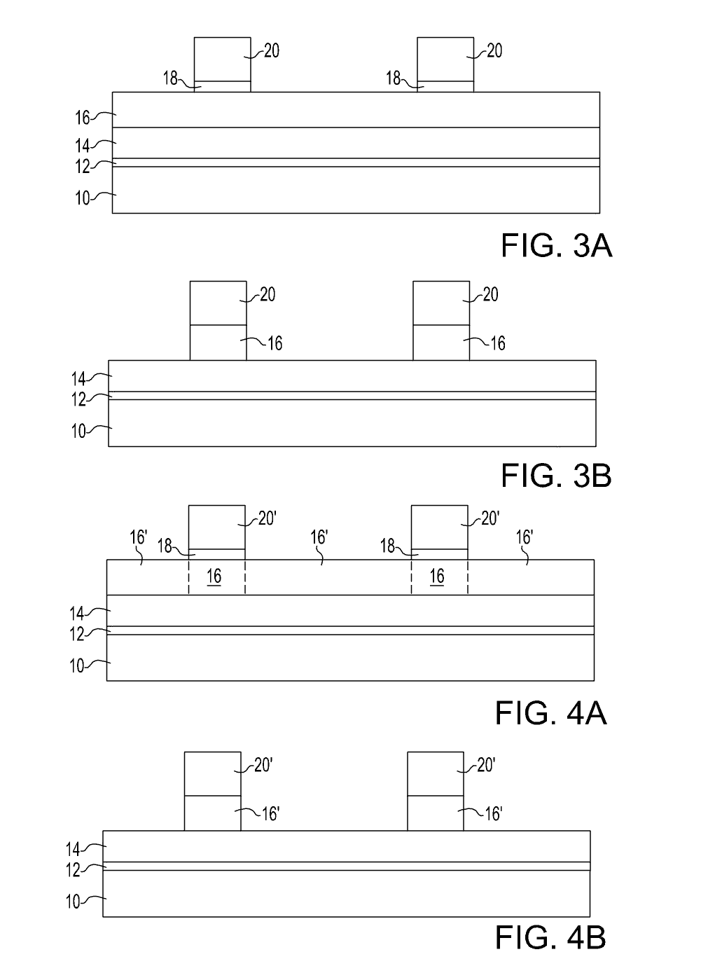

FIGS. 3A-3B are pictorial representations (through cross sectional views) illustrating other patterning schemes that can be subjected to the inventive method. The components within FIGS. 3A-3B are the same as those described in FIGS. 1A-1B, except that the oxide hardmask 18 of FIG. 3A and the organic planarizing material of FIG. 3B are patterning via lithography and etching prior to VUV exposure.

FIGS. 4A-4B are pictorial representations (through cross sectional views) illustrating the structures of FIGS. 3A and 3B, respectively, after VUV exposure. In these drawings, the prime designations represent patterning materials that are affected by VUV exposure. That is, the prime designation denotes patterning materials that have increased crosslinking which is caused by the VUV exposure.

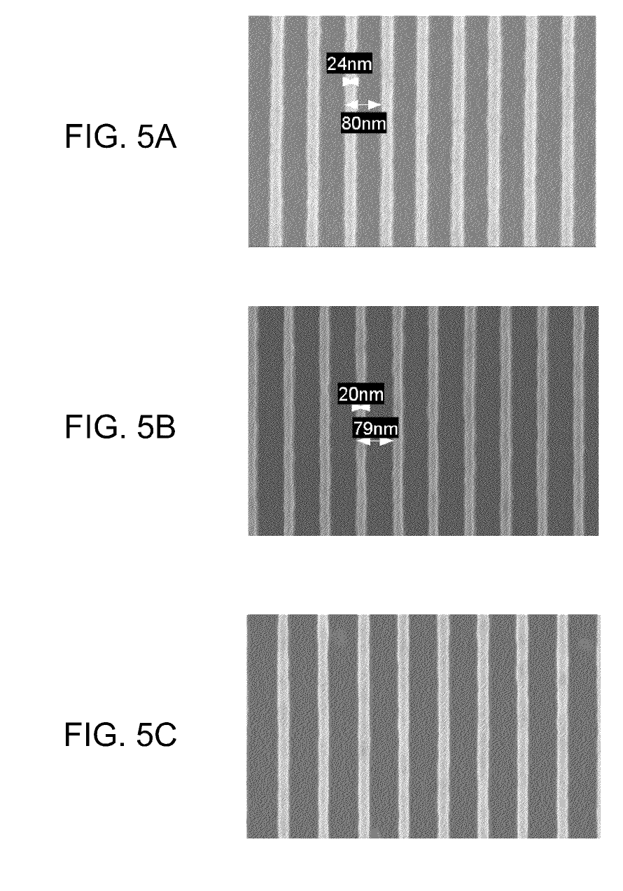

FIGS. 5A-5C are SEMs of 20 nm gate structures which were patterned utilizing the inventive method of the present application, FIG. 5A represents post litho exposure, FIG. 5B represents a post gate etch in which a bottom most preprocessing patterning material has been processed through VUV exposure after one stage of the etch process, and FIG. 5C represents a post gate etch in which two preprocessing patterning materials have been processed through VUV exposure, the topmost material after litho and the bottom most after one stage of the etch process.

While the present invention has been particularly shown and described with respect to preferred embodiments thereof it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A method of fabricating a semiconductor structure having reduced line edge roughness/line width roughness values, comprising:
exposing at least one preprocessed patterning material located on a substrate to vacuum ultra violet (VUV) emissions to induce crosslinking of said at least one preprocessed patterning material, said VUV emissions are generated by an inert species containing plasma.

2. The method of claim 1 wherein said inert species containing plasma comprises at least one of He, Kr, Ar, Xe and Ne.

3. The method of claim 1 wherein said inert species containing plasma comprises He.

4. The method of claim 1 wherein said VUV emissions are generated by subjecting said inert species containing plasma to a pressure of less than 100 mT, a source power of greater than 500 W, a bias power of less than 50 W and a substrate temperature of less than, or equal to, 60° C.

5. The method of claim 4 wherein said pressure is less than 50 mT and said bias power is 0 W.

6. The method of claim 1 wherein said preprocessed patterning material is at least one of a photoresist, a patternable low k dielectric, an planarizing organic material and an antireflective coating (ARC).

7. The method of claim 1 wherein said preprocessed patterning material is subjected to lithography prior to said exposing.

8. The method of claim 1 wherein said preprocessed patterning material is subjected to at least one etching step prior to said exposing.

9. The method of claim 1 wherein said preprocessed patterning material is subjected to lithography and at least one etching step prior to said exposing.

10. The method of claim 1 wherein said substrate further includes at least one material layer to be subsequently patterned during a subsequent etching step.

11. The method of claim 10 wherein said at least one material layer comprises a semiconductor material, a dielectric material, a conductive material or any combination or multilayered stack thereof.

12. The method of claim 11 wherein said at least one material layer is a dielectric material of a FET structure, an interconnect structure, or an insulator structure.

13. The method of claim 11 wherein said at least one material layer is a conductive material of a FET structure.

14. A semiconductor structure comprising at least one feature defined by a patterned material layer, wherein said at least one feature has a line edge roughness (LER) of 1.4 nm or less and a line width roughness (LWR) of 2.3 nm or less.

15. The semiconductor structure of claim 14 wherein said patterned material layer comprises a semiconductor material, a dielectric material, a conductive material or any combination or multilayered stack thereof.

16. The semiconductor structure of claim 15 wherein said patterned material layer is a dielectric material of a FET structure, an interconnect structure, or an insulator structure.

17. The semiconductor structure of claim 15 wherein said patterned material layer is a conductive material of a FET structure.

18. The semiconductor structure of claim 15 wherein said patterned material layer includes a stack of a conductive material located atop a dielectric material.
